(19) United States
(12) Patent Application Publication
(10) Pub. No.: US 2006/0012953 A1
(43) Pub. Date: Jan. 19, 2006

(54) Chassis and method for directing the flow of air through a chassis

(75) Inventors: Richard S. Mills, Cedar Park, TX (US); Mark M. Bailey, Austin, TX (US)

Correspondence Address: Roger Fulghum;Baker Botts L.L.P., One Shell Plaza, 910 Louisiana Street, Houston, TX, 77002-4995, US

(73) Assignee: DELL PRODUCTS L.P.

(21) Appl. No.: 10/890,060

(22) Filed: Jul. 13, 2004

(51) Int. Cl. H05K 7/20

(52) U.S. Cl. 361/690

(57) ABSTRACT

A chassis assembly for an information handling system or computer system is provided in which an outlet assembly coupled to the chassis includes a shelf that is positioned beyond the boundaries of the base of the chassis. The shelf includes an opening for allowing forced air to exit the interior of the information handling system.

### TECHNICAL FIELD

The present disclosure relates generally to the field of information handling systems, including computing systems, and, more particularly, to a chassis and a method for directing the flow of air through a chassis.

### BACKGROUND

As the value and use of information continues to increase, individuals and businesses continually seek additional ways to process and store information. One option available to users of information is an information handling system. An information handling system generally processes, compiles, stores, and/or communicates information or data for business, personal, or other purposes thereby allowing users to take advantage of the value of the information. Because technology and information handling needs and requirements vary between different users or applications, information handling systems may also vary with regard to the kind of information that is handled, how the information is handled, how much information is processed, stored, or communicated, and how quickly and efficiently the information may be processed, stored, or communicated. The variations in information handling systems allow for information handling systems to be general or configured for a specific user or specific use, including such uses as financial transaction processing, airline reservations, enterprise data storage, or global communications. In addition, information handling systems may include a variety of hardware and software components that may be configured to process, store, and communicate information and may include one or more computer systems, data storage systems, and networking systems.

An information handling system may include a chassis, which serves as a frame or base for the physical components of the computer system. The components of the information handling system, including any printed circuit boards and power supplies, are positioned on or within the chassis. A cover may be coupled to the chassis to form a complete enclosure for the internal contents of the information handling system.

A critical consideration in the operation of an information handling system is the cooling of the interior of the system. Components within the interior of the computer system generate heat, and this heat must be dissipated or evacuated from the interior of the computer system. Excessive heat within the interior of a computer can harm the operation of the components of the computer system. Complicating the dissipation of heat within a computer system is the desire for increasingly smaller chassis configurations in computer systems that, despite their size, are able to meet increasingly higher performance characteristics. In this environment, the chassis and interior of a computer system may be crowded with components, effectively reducing or eliminating the pathway for the flow of air for the purpose of heat dissipation within the interior computer system.

### SUMMARY

In accordance with the present disclosure, a chassis assembly for an information handling system or computer system is provided in which an outlet assembly coupled to the chassis includes a shelf that is positioned beyond the boundaries of the base of the chassis. The shelf includes an opening for allowing forced air to exit the interior of the information handling system. The plane of the shelf is generally parallel to the plane of the base of the chassis.

A technical advantage of the chassis design disclosed herein is that the disclosed chassis design does not consume space within the computer system or the surface area of the base of the chassis. The information handling system that is associated with the chassis design is able to achieve improved air cooling characteristics of the design while not sacrificing valuable space within the interior of the computer system. Another technical advantage of the chassis design disclosed herein is that the design does not cause the associated information handling system or computer system to exceed the applicable height requirements for rack-mounted devices. As such, devices using the chassis design disclosed herein can be used with racks having standardized size constraints. Other technical advantages will be apparent to those of ordinary skill in the art in view of the following specification, claims, and drawings.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 is a pictorial view of a chassis assembly;

FIG. 2 is a first pictorial view of an outlet assembly of a chassis assembly; and

FIG. 3 is a second pictorial view of an outlet assembly of a chassis assembly.

### DETAILED DESCRIPTION

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a person computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk storage drives, one or more network ports for communication with external devices as well as various input and output (I/O) devices, such as a keyboard, a mouse, and a video display. The information handling system may also include one or more buses operable to transmit communications between the various hardware components. An information handling system may include a chassis assembly.

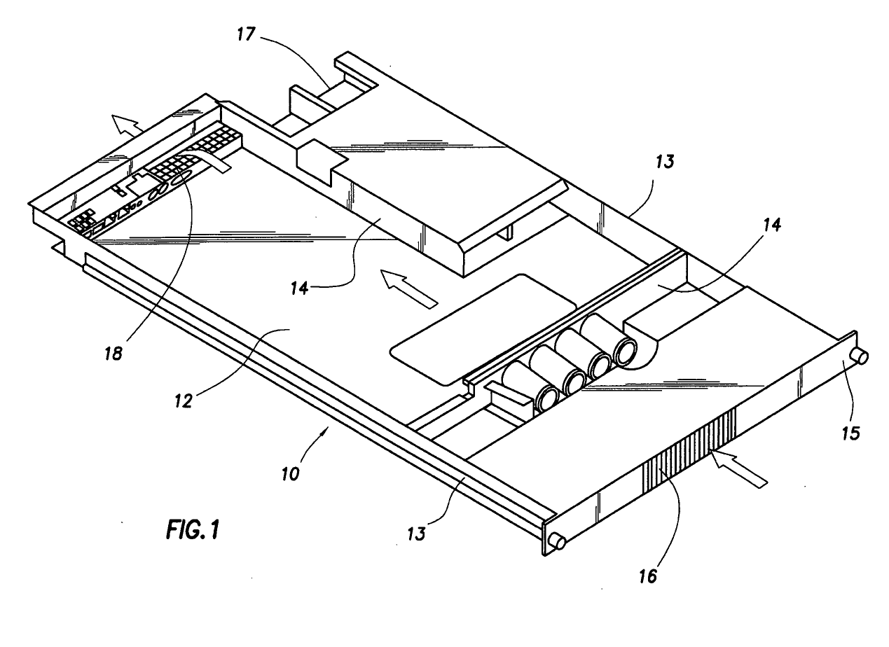

Shown in FIG. 1 is a chassis assembly, which is indicated generally at 10, for a computer system or other information handling system. Chassis assembly 10 includes a base 12 that is bounded by a sides 13, a front plate 15, and a rear edge 17. Chassis assembly 10 includes a number of partition elements 14 that serve the purpose of separating the surface area of the base of the chassis assembly into defined regions. Separating the surface area of base 12 into regions establishes boundaries for the placement of components of the computer system within the chassis of the computer system. The manufacture of a computer system involves the placement of components within the chassis. The chassis is coupled to an upper cover and a lower cover to form an enclosure for the components of the computer system.

Rack-mounted devices, including server systems, have predefined size limitations or characteristics. These characteristics define limitations to the shape or dimensions of rack-mounted devices so that devices of different manufacturers may fit within racks having a standardized shape. One standard of measurement for rack-mounted devices is the height of the device. The height of a 1U rack-mounted device is 1.75″; the height of a 2U device is 3.50″; the height of a 3U device is 5.25″; the height of a 4U device is 7.00″ and so on. The chassis of FIG. 1 is a chassis for a 1U rack-mounted device.

The flow of air through the interior of the chassis is indicated by the larger arrow, which will be referred to herein as the air flow indicator. The air flow is created and directed by one or more fans (not shown) in the interior of the computer system and positioned within the chassis. The fans create a flow of air through the interior of the computer system. The air flow absorbs heat from the interior of the computer system. The heated air then exits the interior of the computer system. In the chassis of the example of FIG. 1, air enters the chassis though an air flow inlet 16 and exists the chassis through an air flow outlet assembly 18. It should be recognized that a flow of air through the interior of the computer system could be caused by an element or condition other than one or more fans positioned in the interior of the computer system.

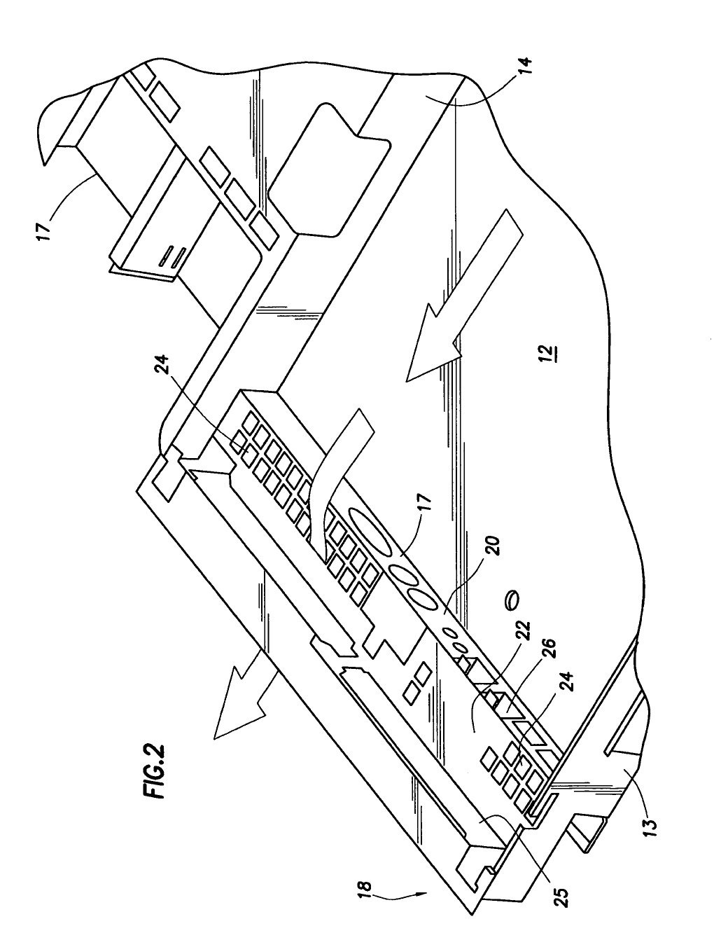

FIG. 2 is a closer view of the air flow outlet assembly 18 in the rear of chassis assembly 10. A lower rear plate 20 is coupled to base 12 of the chassis assembly. Formed in lower rear plate 20 are a number of openings for data and power connections to components housed within the computer system. A shelf 22 is coupled to lower rear plate 20 and is arranged so that the plane of shelf 22 is generally parallel to the plane of base 12. The height of shelf 22, which is defined as the distance between the plane of shelf 22 and the plane of base 12, is roughly half of the height of sides 13. Coupled to shelf 22 is an upper rear plate 25, the plane of which is generally parallel to the plane of lower rear plate 20. Upper rear plate 25 extends to the height of sides 13 of the chassis assembly so that, when an upper cover and a lower cover (not shown) are placed around chassis assembly 10, an enclosure is formed. The intersection of lower rear plate 20 and base 12 forms a portion of the rear edge 17 of chassis assembly 10. Shelf 22 extends a distance beyond the rear edge 17 such that shelf 22 is not above base 12 of the chassis assembly. Shelf of FIG. 2 extends for only a portion of the length of rear edge 17.

Formed within shelf 22 are a number of air flow openings 24. The plurality of air flow openings 24 are formed in the shape of a lattice to allow the flow of air while prevent objects from entering the interior of the computer system. A pathway for the flow of air though the air flow openings 24 of shelf 22 is shown in FIG. 2. The flow of air is indicated by the air flow indicator. As indicated in FIG. 2, the arrangement of air flow outlet assembly 18 permits air to flow out of the rear of the chassis, while preserving the space within the interior of the chassis. The air flow openings of shelf 22 are generally not positioned above the base of the chassis. To provide for the flow of air through the rear of the chassis assembly, a shelf 22 is extended outward a distance beyond the rear edge of the chassis assembly. Shelf 22, which is elevated a distance between the base of the chassis assembly and the height of the sides of the chassis assembly, includes a number of air flow openings 24 for the passage of air. The shelf is arranged in the chassis such that the shelf does not consume space in the interior of the chassis.

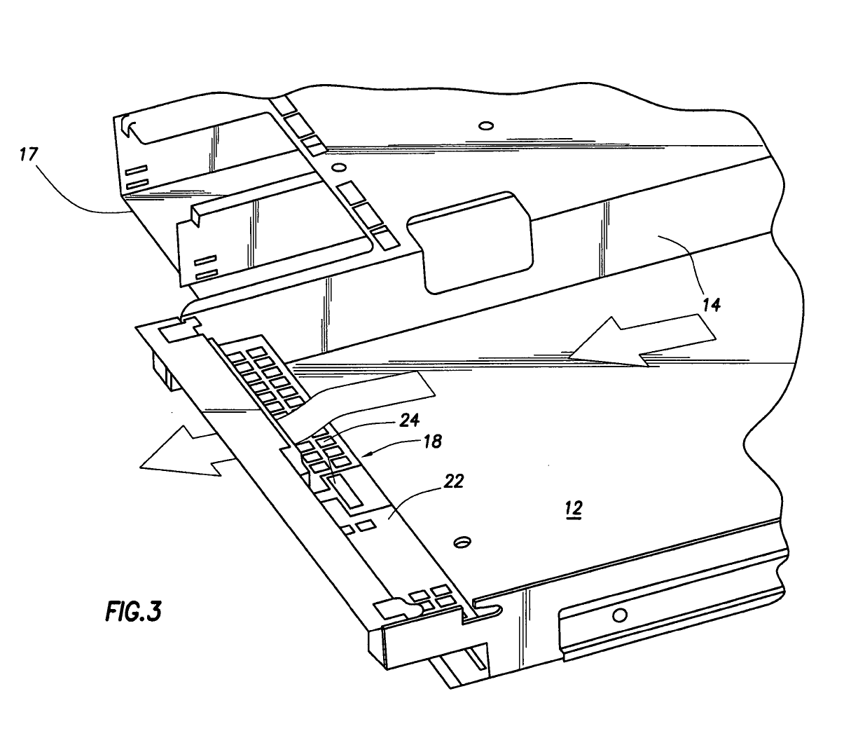

Shown in FIG. 3 is another view of the air flow outlet assembly 18 in the rear of chassis assembly 10. The flow of air of FIG. 3 is indicated by the air flow indicator. As indicated with respect to FIG. 2, air flow outlet assembly 18 includes a shelf 22 that includes a number of air flow openings 24. As can be seen from FIGS. 2 and 3, shelf 22 is sufficiently higher than base 12 that shelf 22 does not interfere with those data and power connections coupled to the computer system through lower rear plate 20. Similarly, the flow of air through the air flow openings 24 is not obstructed by presence of any data or power connections.

The structure of the chassis described herein provides for increased cooling within the interior of the chassis without consuming additional space within the interior of the chassis. Although the height of a rack-mounted is bounded by a standardized height requirement, a chassis, and is associated rack-mounted device, do not have a fixed length. The design of the chassis described herein extends a shelf a short distance beyond the rear edge of the base of the chassis to provide for a locations of air flow outlets that are easily reached by the air flow that is traversing the interior of the computer system. Although the placement of shelf a short distance beyond the rear edge of the base of the chassis does extend the length of the chassis assembly, the increased length is not significant in terms of operation or physical configuration and improves the operational capability of the associated computer system.

Although the chassis and the method for directing air flow through a chassis has been described herein with reference to a computer system, it should be recognized that chassis and method disclosed herein may be used with varieties of information handling systems other than computer systems. Although the chassis design disclosed herein has been described with respect to a 1U rack-mounted device, the chassis design disclosed herein has equal applicability to rack-mounted devices of heights other than the 1.75″ height of a 1U device. Although this specification often speaks of various surfaces (base, sides, walls, shelves) being coupled to one another, it should be recognized that the chassis described herein could be formed of a single sheet of metal or other material. As such, surface may be formed by manipulating a single piece of material to form multiple surfaces that are said to be coupled to one another, as the term coupled is used in this disclosure. Although the present disclosure has been described in detail, it should be understood that various changes, substitutions, and alterations can be made hereto without departing from the spirit and the scope of the invention as defined by the appended claims.

1. A chassis assembly for an information handling system, comprising:
a base having first and second sides opposite the plane of the base;
an air inlet proximate a front portion of the base; and
an air outlet assembly proximate a rear portion of the base, the air outlet comprising,
a first surface coupled to an edge of the base; and
a second surface coupled to the first lower surface and generally parallel to the plane of the surface of the base, wherein the second surface includes a number of openings formed therein for the passage of air therethrough, and wherein the openings of the second surface are not above the surface of the base.

2. The chassis assembly of claim 1, wherein the distance between the second surface of the air outlet assembly and the plane of the surface of the base is generally half of the height of the sides of the chassis assembly.

3. The chassis assembly of claim 1, wherein the first surface of the air outlet assembly includes a number of openings for receiving data or power communications to the information handling system.

4. The chassis assembly of claim 1, wherein the size of the elements of the chassis assembly are such that the chassis assembly may be used in a rack-mounted information handling system that meets a 1U height limitation.

5. The chassis assembly of claim 1, wherein the base includes a rear edge, at least a portion of which is formed by the intersection of the first surface of the air outlet assembly and the base.

6. The chassis assembly of claim 1, wherein the rear edge of the base is disposed between the base and the openings of the second surface of the air outlet assembly.

7. A method for directing air through an air inlet and out of an air outlet assembly of a chassis for an information handling system, wherein the chassis includes a base having first and second sides opposite the plane of the base, comprising the steps of:
drawing in air through the air inlet opening; and
forcing air out of the air outlet assembly,
wherein the air outlet assembly, comprises
a first surface coupled to an edge of the base; and
a second surface coupled to the first lower surface and generally parallel to the plane of the surface of the base, wherein the second surface includes a number of openings formed therein, and wherein the openings of the second surface are not above the surface of the base; and
wherein the air is forced out of the outlet assembly through the openings formed in the second surface.

8. A method for directing air through an air inlet and out of an air outlet assembly of a chassis for an information handling system of claim 7, wherein the first surface of the air outlet assembly includes a number of openings for receiving data or power communications to the information handling system.

9. A method for directing air through an air inlet and out of an air outlet assembly of a chassis for an information handling system of claim 8, wherein the air is drawn into the air inlet opening and forced out of the air outlet assembly by a fan positioned proximate the base of the chassis.

10. A chassis for a computing system, comprising:
a base, wherein the base comprises,
first and second sides that are opposite the planar surface of the base;
an air inlet proximate a front portion of the base;
a rear edge that is opposite the planar surface of the base from the air inlet; and
an air outlet assembly, wherein the air outlet assembly comprises,
a lower rear surface formed at the rear edge of the base;
a shelf surface coupled to the lower rear surface, wherein the shelf surface is generally parallel to the planar surface of the base, and wherein the shelf surface has an air opening formed therein for the passage of air therethrough, wherein the air opening of the shelf surface is not above the planar surface of the base of the chassis.

11. The chassis of claim 10, wherein the lower rear surface includes a plurality of openings formed therein for receiving data and communications links to be coupled to elements within the interior of the computing system.

12. The chassis of claim 10, wherein the shelf is generally parallel to the planar surface of the base.

13. The chassis of claim 12, further comprising an upper rear surface coupled to the shelf surface.

14. The chassis of claim 13, wherein the top edge of the upper rear surface is generally of the same height as the sides of the base.

15. The chassis of claim 14, wherein the upper rear surface does not include an opening for the passage of forced air therethrough.

16. The chassis of claim 10, wherein the shelf surface of the air outlet assembly includes a number of air openings in the form of a lattice.

17. A method for forcing air through a chassis of a computing system, comprising the steps of:
providing a chassis, wherein the chassis comprises,
a base having a planar surface;
a pair of sides opposite the planar surface;
an air inlet proximate a front portion of the base; and
an air outlet assembly proximate a rear edge of the base; wherein the air outlet assembly comprises,
a lower surface coupled to the planar surface of the base at the rear edge of the base; and
a shelf surface coupled to the lower surface, wherein the shelf surface is generally parallel to the planar surface of the base and wherein the shelf surface includes an opening formed therein such that the opening is not above the planar surface of the base.
drawing air into the computing system through the air inlet; and
forcing air out of the computing system through the opening formed in the shelf surface of the air outlet assembly.

18. The method for forcing air through a chassis of a computing system of claim 17, wherein the lower surface of the air outlet assembly includes a plurality of openings formed therein for receiving data and communications links to be coupled to elements within the interior of the computing system.

19. The method for forcing air through a chassis of a computing system of claim 18, wherein the shelf surface of the air outlet assembly is generally parallel to the planar surface of the base.

20. The method for forcing air through a chassis of a computing system of claim 19, wherein the air is drawn into the air inlet and forced out of opening in the shelf surface by a fan positioned proximate the base of the chassis.
